(19) United States
(12) Patent Application Publication
(10) Pub. No.: US 2003/0082881 A1
(43) Pub. Date: May 1, 2003

(54) Method for manufacturing a self-aligned MOS transistor

(76) Inventors: Ting-Chang Chang, Hsin-Chu City (TW); Huang-Chung Cheng, Hsin-Chu City (TW); Cheng-Jer Yang, Tao-Yuan (TW)

Correspondence Address: POWELL, GOLDSTEIN, FRAZER & MURPHY LLP, P.O. BOX 97223, WASHINGTON, DC, 20090-7223, US

(21) Appl. No.: 10/117,043

(22) Filed: Apr. 8, 2002

Related U.S. Application Data
(60) Provisional application No. 60/336,383, filed on Oct. 31, 2001.

(51) Int. Cl. H01L 21/336; H01L 21/44

(52) U.S. Cl. 438/303; 438/301; 438/656

(57) ABSTRACT

The present invention provides a method to form a self-aligned MOS transistor with a gate capped by a metal silicide layer. The gate has a larger surface area and a lower resistance, so this method is suitable as the feature size of integral circuits scale down. In this method, the primary step is to deposit a selective dielectric layer, such as polysilicon germanium layer, on the top of a gate to increase the surface area of the gate. Then, a metal silicide layer is formed on the surface of the dielectric layer to decrease the resistance of the gate. Therefore, comparing to conventional methods, a gate formed by the present method has a larger contacting area and is more ease to connect to a conductive line, so that the performance of a MOS transistor can be improved.

### BACKGROUND

1. Field of the Invention

The present invention generally relates to a method for manufacturing a MOS transistor, and in particular to a method for manufacturing a MOS transistor with a gate which is capped by a self-aligned dielectric material to increase the surface area of the gate.

2. Description of the Prior Art

A conventional method of forming a MOS transistor generally comprises the following steps: firstly, as shown in FIG. 1A, a substrate 10 is provided, and then a gate oxide layer 20 is formed on the substrate 10. Secondly, a gate 20 is formed on the gate oxide layer 15. Afterward, an ion implantation process is performed to form a lightly doped drain 25 and a lightly doped source 30 by using the gate 20 as a mask. A sidewall 40 of the gate 20 is then formed, as shown in FIG. 1B. Another ion implantation process is performed to form a drain 45 and a source 50, by using the gate 20 and the sidewall 40 as a mask. Thus, a MOS transistor is completed. However, when the feature size of integral circuit becomes more and more small, the size of a gate should also be scaled down. Therefore, the contacting area of a gate and a conductive line also becomes smaller, so that the resistance will increase and the performance of the MOS transistor will be degraded. This problem can be solved by a method of increasing the conductivity of a gate. A recent technique is to form a metal silicide layer, such as titanium silicide, cobalt silicide, and nickel silicide, on the surface of a gate to decrease the resistance of the gate. In this method, a metal layer 55, such as titanium, cobalt, and nickel, is firstly deposited to cover a MOS transistor, as shown in FIG. 1D. Then, a heating process is performed to make the polysilicon on the surface of the gate 20, the drain 25, and the source 30 react with the metal to form metal silicide layer (60, 65, 70), as shown in FIG. 1E. Finally, the metal layer 55 is then removed, as shown in FIG. 1F.

However, the above method can decrease the resistance of a gate, but it is still difficult to form conductive lines in a scaled-down feature size. Therefore, another efficient method is to increase the surface area of a gate.

### SUMMARY

It is an object of the invention to provide a method for forming a MOS transistor.

It is another object of the invention to provide a method to increase the surface area of a gate.

It is a further object of the invention to provide a method to reduce the resistance of a gate.

According to the foregoing objects, the present invention provides an efficient method, which comprises the following steps: firstly, a structure is provided. The structure comprises a substrate, a gate oxide layer on the substrate, and a gate on the gate oxide layer. Then an ion implantation process is performed to form a lightly doped drain and a lightly doped source. Secondly, a first dielectric layer, such as a silicon oxide layer or a silicon nitride layer, is deposited to cover the gate, the gate oxide layer, the lightly doped drain, and the lightly doped source. Then, an etching process is performed to remove a part of the first dielectric layer, so that a partial region of the top of the gate is exposed. Afterward, a second dielectric layer, such as a polysilicon germanium layer, is selectively deposited on the surface of said exposed partial region of the top of the gate. The surface area and width of the second dielectric layer are larger than that of the exposed partial region of the gate. It should be noted that the second dielectric layer is only deposited on the gate made of polysilicon, but not on the first dielectric layer. Hence, the process is self-aligned. And this deposition process is performed by chemical vapor deposition at a temperature range between 500° C. and 700° C. Then, by using the second dielectric layer as a mask, a part of the first dielectric layer is removed to expose the lightly doped drain and the lightly doped source, and the remaining part of the first dielectric layer which is shielded by the second dielectric layer is used to be a sidewall of the gate. Afterward, an ion implantation process is performed to form a drain and a source.

Furthermore, a metal layer, such as titanium, cobalt, and nickel, can be deposited to cover the second dielectric layer, the drain, and the source. Then, a heating process is performed to make the polysilicon on the surface of the second dielectric layer, the drain, and the source react with the metal to form metal silicide layers. These metal silicide layers can reduce the resistances of the gate, the drain, and the source. The above metal layer can be deposited by an ionized metal plasma (IMP) method. Consequently, a MOS transistor formed by the present method will have a gate with a larger surface area and lower resistance.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG.1A to FIG. 1F show a series of schematic cross-sectional diagrams of a conventional method of forming a MOS transistor with metal silicide layers; and

FIG. 2A to FIG. 2I show a series of schematic cross-sectional diagrams of the present method for forming a self-aligned MOS transistor.

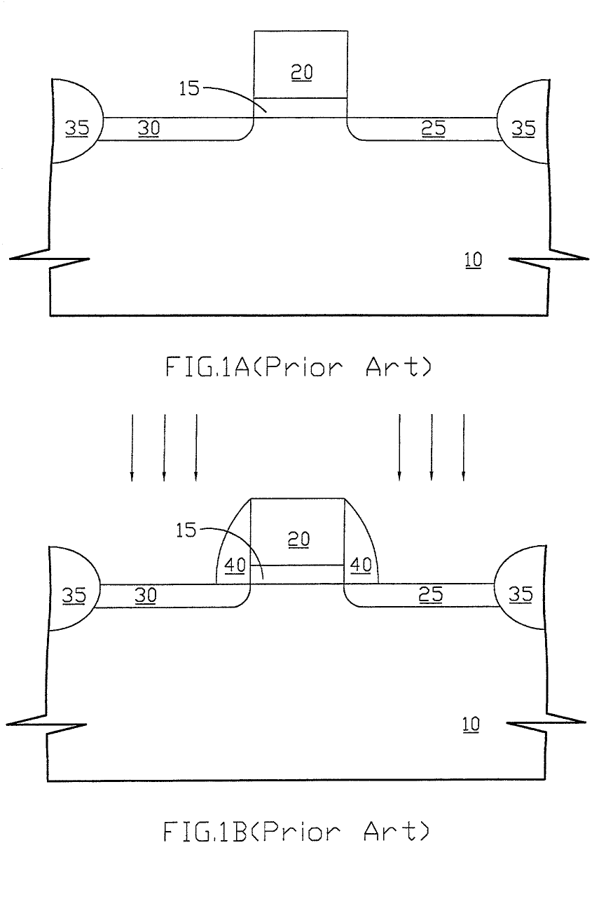

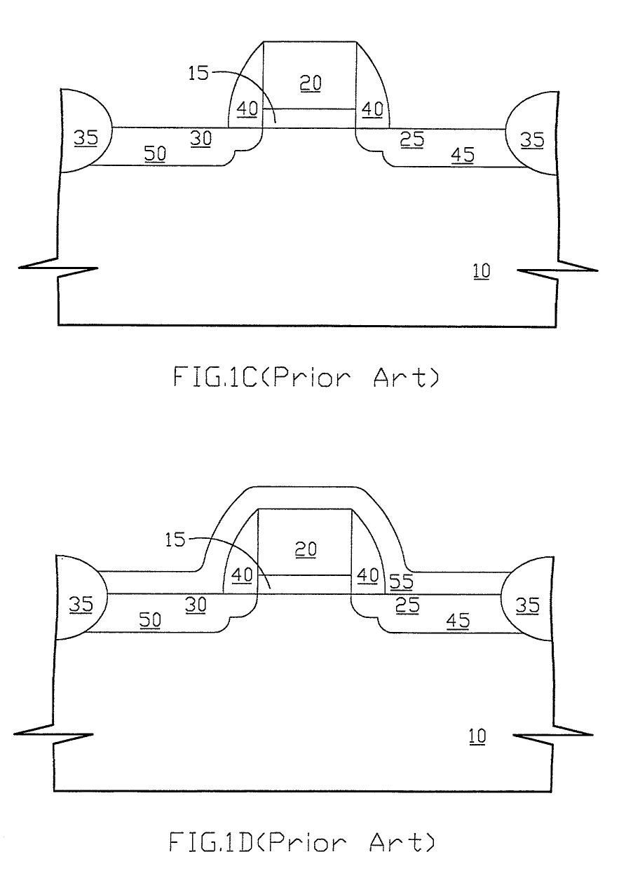

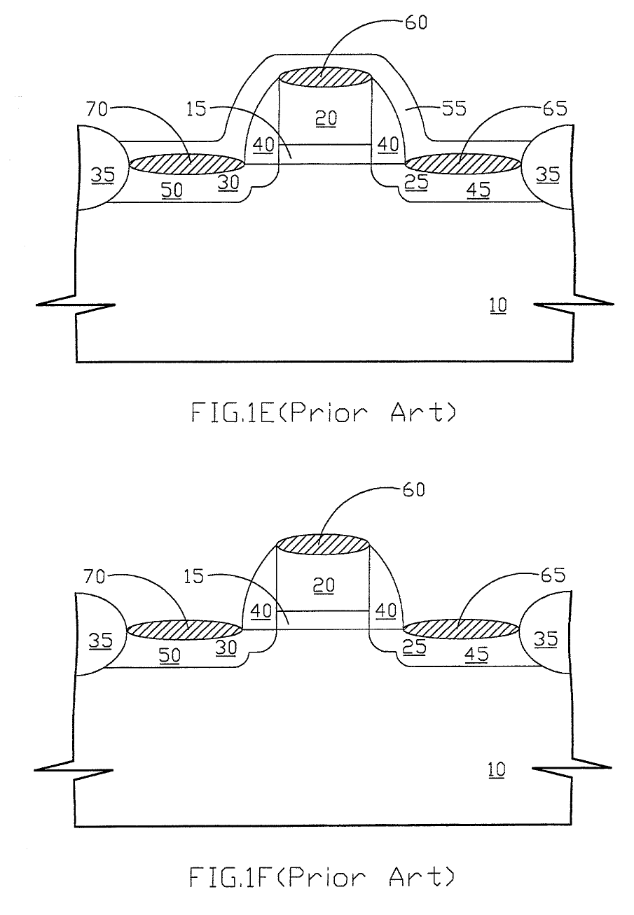

### DESCRIPTION OF THE PREFERRED EMBODIMENT

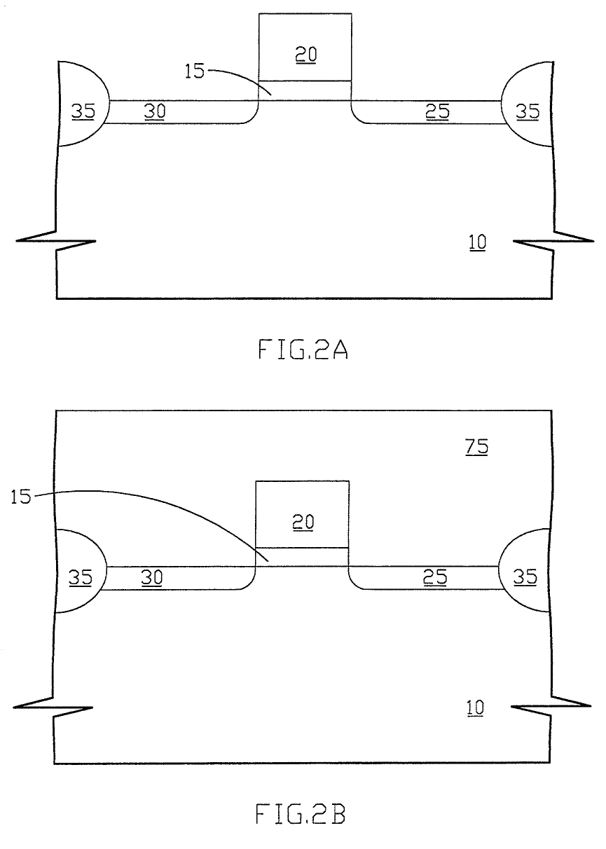

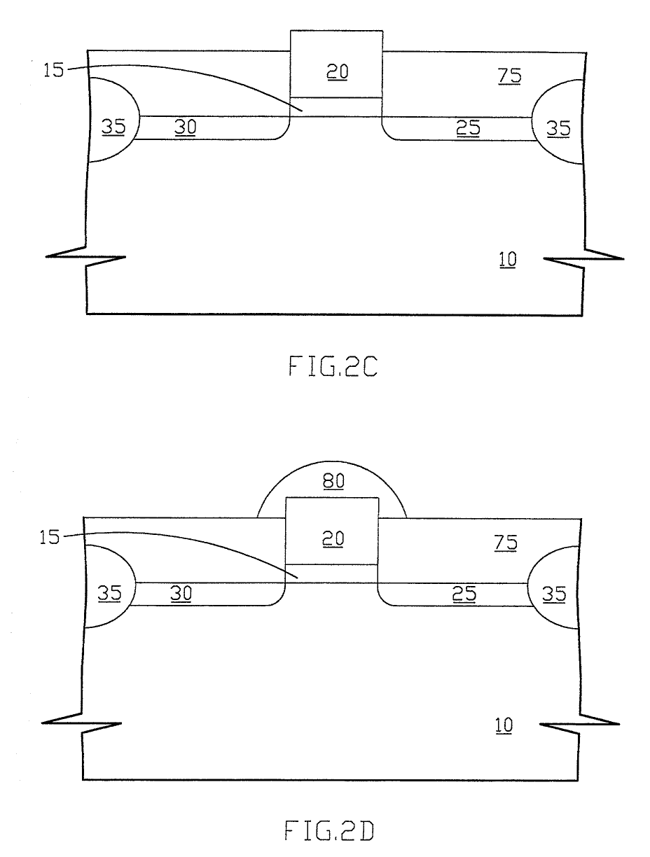

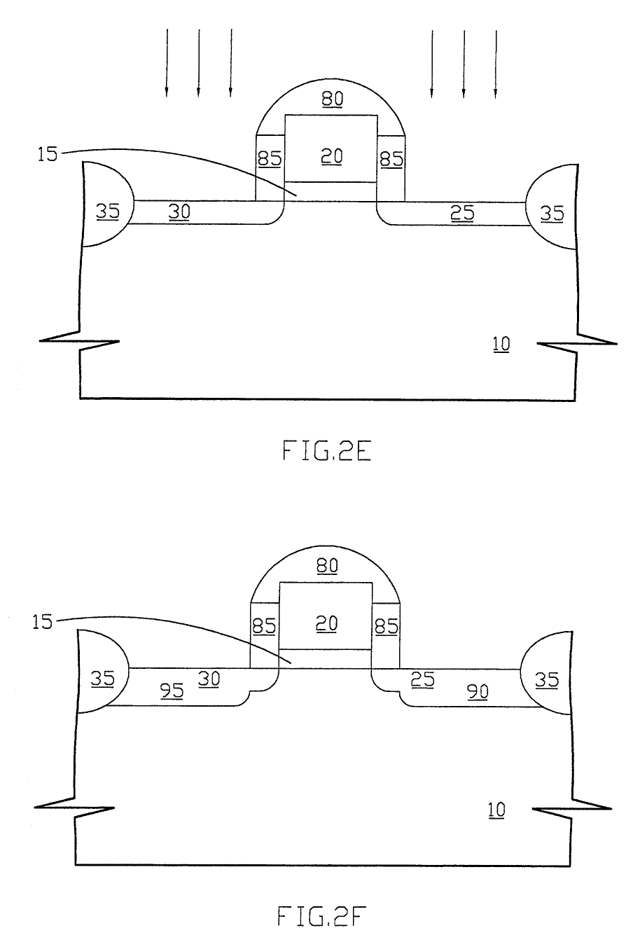

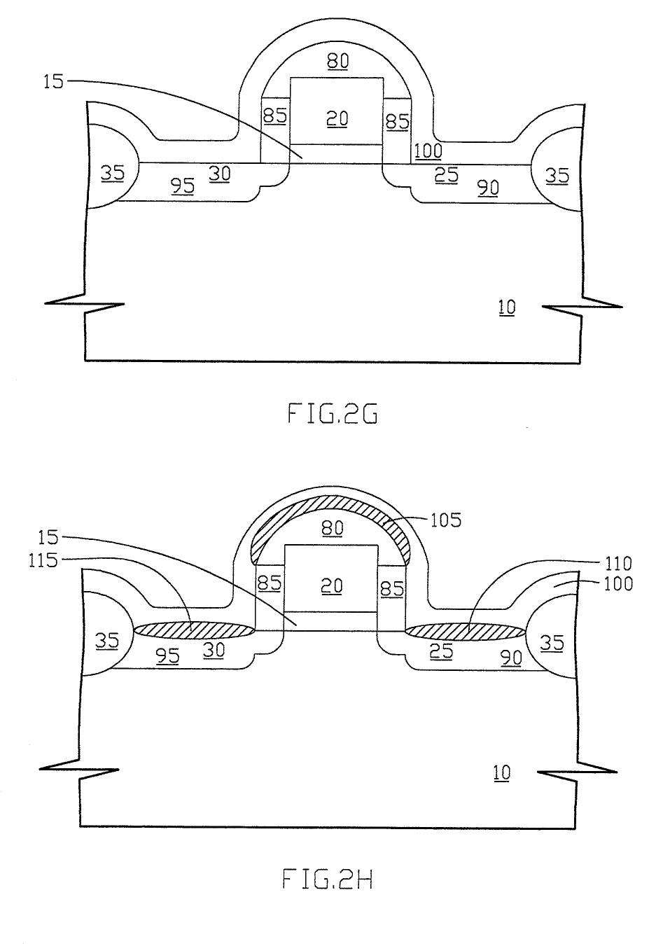

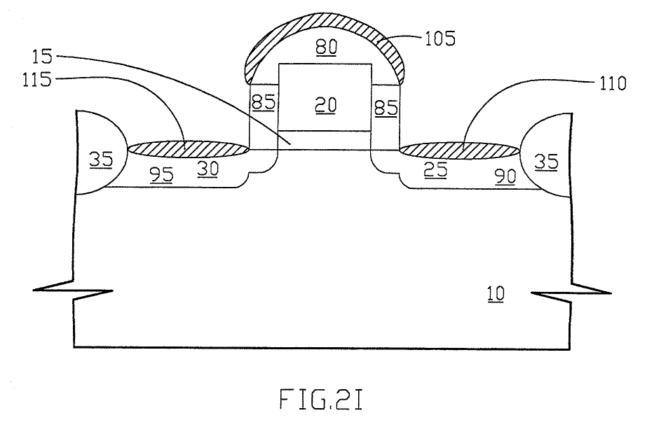

We provide a method in the present invention to efficiently increase the surface area of a gate, and the details are described as the following: firstly, as shown in FIG. 2A, a substrate 10 is provided, and then a gate oxide layer 15 is formed on the substrate 10. Secondly, a polysilicon layer is deposited on the gate oxide layer 15, and the polysilicon layer is then etched to form a gate 20. Afterward, an ion implantation process is performed to form a lightly doped drain 25 and a lightly doped source 30 by using the gate 20 as a mask. All MOS transistors are separated one another by forming field oxide layers 35, as shown in FIG. 2A. Then, a first dielectric layer 75, such as a silicon oxide layer or a silicon nitride layer, is deposited to cover the gate 20, the gate oxide layer 15, the lightly doped drain 25, and the lightly doped source 30, as shown in FIG. 2B. An etching process is then performed to remove a part of the first dielectric layer 75, so that a partial region of the top of the gate 20 is exposed, as shown in FIG. 2C. Afterward, a second dielectric layer 80 is deposited to cover said partial region of the top of the gate 20 by using a chemical vapor deposition method in a temperature range between 500° C. and 700° C., as shown in FIG. 2D. The material of the second dielectric layer 80 is a selectively depositing material, such as polysilicon germanium, which is only deposited on the surface of the gate 20 made of polysilicon, but not on the surface of the first dielectric layer 75. Thus, this depositing process is self-aligned. As shown in FIG. 2D, we can find that the surface area and width of the second dielectric layer 80 are larger than that of said partial region of the gate 20. Hence, it is not only good for a connection between the gate and a conductive line, but also good for increasing the contacting area. Then, by using the second dielectric layer 80 as a mask, an anisotropic etching process is performed to remove a part of the first dielectric layer 75, so that the most part of the lightly doped drain 25 and the lightly doped source 30 are exposed. The remaining part of the first dielectric layer 75 beneath the second dielectric layer 80 is used to be a sidewall 85 of the gate 20, as shown in FIG. 2E. Afterward, by using the second dielectric layer 80 as a mask again, an ion implantation process is performed to form a drain 90 and a source 95, as shown in FIG. 2F. Then, a metal layer 100, such as titanium, cobalt, and nickel, is deposited on the surface of the MOS transistor by an ionized metal plasma (IMP) method, as shown in FIG. 2G. Then, a heating process is performed, and the metal layer 100 will react with the second dielectric layer 80, the drain 90, and the source 95, so that metal silicide layers (105, 110, 115) are formed, as shown in FIG. 2H. These metal silicide layers (105, 110, 115) can reduce the resistances of the gate 20, the drain 90, and the source 95, therefore, this method can avoid those problems caused by the decrease of feature size. Finally, the metal layer 100 is removed, as shown in FIG. 21. Then, a MOS transistor is completed.

Although specific embodiments have been illustrated and described, it will be obvious to those skilled in the art that various modifications may be made without departing from what is intended to be limited solely by the appended claims.

What is claimed is:

1. A method for increasing the surface area of a gate, said method comprising the steps of:
providing a structure, said structure comprises a substrate, a gate oxide on said substrate, and a gate on said gate oxide, wherein said substrate comprises a lightly doped drain and a lightly doped source;
forming a first dielectric layer to cover said substrate, said lightly doped drain, said lightly doped source, and said gate oxide;
etching said first dielectric layer to expose a partial region of said gate;
selectively depositing a second dielectric layer to cover said partial region of said gate, wherein said partial region of said gate was wrapped in said second dielectric layer; and
using said second dielectric layer as a mask, and etching a part of said first dielectric layer to expose said lightly doped drain and said lightly doped source, and the remaining part of said first dielectric layer on the surface of said gate is used to be a sidewall of said gate.

2. The method according to claim 1, said method further comprising a step of performing an ion implantation process to form a drain and a source.

3. The method according to claim 1, wherein said first dielectric layer is a silicon oxide layer.

4. The method according to claim 1, wherein said first dielectric layer is a silicon nitride layer.

5. The method according to claim 1, wherein said second dielectric layer is a polysilicon germanium layer.

6. The method according to claim 5, wherein said polysilicon germanium layer is formed by a chemical vapor deposition process.

7. The method according to claim 6, wherein said chemical vapor deposition process is performed at a temperature range between about 25° C. and about 40° C.

8. The method according to claim 1, said method further comprising the steps of:
performing an ion implantation process to form a drain and a source;
forming a metal layer to cover said drain, said source, said sidewall, and said second dielectric layer;
performing a heating process to form a metal silicide layer on the surface of said second dielectric layer; and
removing said metal layer.

9. The method according to claim 8, wherein the material of said metal layer is selected from the group consisting of titanium, cobalt, and nickel.

10. The method according to claim 8, wherein said metal layer is deposited by an ionized metal plasma (IMP) method.

11. A method for manufacturing a MOS transistor, said method comprising the steps of:
providing a substrate;
forming a gate oxide layer on said substrate;
forming a gate on said gate oxide layer;
forming a lightly doped drain and a lightly doped source on said substrate;
depositing a first dielectric layer to cover said substrate, said gate, said lightly doped drain and said lightly doped source;
etching said first dielectric layer to expose a partial region of said gate;
selectively depositing a second dielectric layer to cover said partial region of said gate, wherein said partial region of said gate was wrapped in said second dielectric layer;
Using said second dielectric layer as a mask, and etching a part of said first dielectric layer to expose said lightly doped drain and said lightly doped source, and the remaining part of said first dielectric layer on the surface of said gate is used to be a sidewall of said gate;
performing an ion implantation process to form a drain and a source;
depositing a metal layer to cover said drain, said source, said sidewall, and said second dielectric layer;
performing a heating process to form a metal silicide layer on the surface of said second dielectric layer; and
removing said metal layer.

12. The method according to claim 11, wherein said first dielectric layer is a silicon oxide layer.

13. The method according to claim 11, wherein said first dielectric layer is a silicon nitride layer.

14. The method according to claim 11, wherein said second dielectric layer is a polysilicon germanium layer.

15. The method according to claim 11, wherein said polysilicon germanium layer is formed by a chemical vapor deposition process.

16. The method according to claim 11, wherein said chemical vapor deposition process is performed at a temperature range between about 25° C. and about 40° C.

17. The method according to claim 11, wherein the material of said metal layer is selected from the group consisting of titanium, cobalt, and nickel.

18. The method according to claim 11, wherein said metal layer is deposited by an ionized metal plasma (IMP) method.
